(19) United States
(12) Patent Application Publication
(10) Pub. No.: US 2023/0078310 A1
(43) Pub. Date: Mar. 16, 2023

(54) METHOD OF DETECTING DEVIATION AMOUNT OF SUBSTRATE TRANSPORT POSITION AND SUBSTRATE PROCESSING APPARATUS

(71) Applicant: Tokyo Electron Limited, Tokyo (JP)

(72) Inventors: Joji TAKAYOSHI, Miyagi (JP); Yuri KIMURA, Miyagi (JP)

(73) Assignee: Tokyo Electron Limited, Tokyo (JP)

(21) Appl. No.: 17/943,702

(22) Filed: Sep. 13, 2022

(30) Foreign Application Priority Data
Sep. 14, 2021 (JP) 2021-149088

(51) Int. Cl. H01L 21/67; H01L 21/311; H01J 37/32

(52) U.S. Cl. CPC H01L 21/67265; H01L 21/31116; H01L 21/31138; H01L 21/67253; H01J 37/32724; H01J 2237/3341

(57) ABSTRACT

A method of detecting a deviation amount of a substrate transport position includes: setting a temperature of a substrate support surface to the same temperature over an entire substrate support surface; etching a first etching target film formed on a substrate; acquiring a first etching rate that is an etching rate of the first etching target film; setting the temperature of the substrate support surface to be concentrically and gradually increased from a central portion to a peripheral edge portion; etching a second etching target film formed on the substrate, the second etching target film being same kind as the first etching target film; acquiring a second etching rate that is an etching rate of the second etching target film; calculating a difference between the acquired first etching rate and second etching rate; and calculating the deviation amount of the substrate transport position based on the calculated difference.

### CROSS-REFERENCE TO RELATED APPLICATIONS

This application is based on and claims priority from Japanese Patent Application No. 2021-149088, filed on Sep. 14, 2021 with the Japan Patent Office, the disclosure of which is incorporated herein in its entirety by reference.

### TECHNICAL FIELD

The present disclosure relates to a method of detecting a deviation amount of a substrate transport position, and a substrate processing apparatus.

### BACKGROUND

When performing an etching processing in a substrate processing apparatus, an electrostatic chuck (ESC) is periodically replaced because it is consumable. It is known that a replaced ESC contains an error in the installation position thereof, and, therefore, leads to a relative positional deviation between the ESC and a substrate, causing an adverse effect on the properties of the substrate. Against this backdrop, it is known to perform so-called teaching for storing positional coordinates in a controller while visually confirming the transport position of a substrate, in order to correct a relative positional error between a susceptor and the substrate. See, for example, Japanese Patent Laid-Open Publication No. 2000-127069.

### SUMMARY

An aspect of the present disclosure relates to a method of detecting a deviation amount of a substrate transport position in a substrate processing apparatus. The substrate processing apparatus includes a process module in which a stage having a substrate support surface is provided inside a chamber, and a controller capable of concentrically controlling a temperature of the substrate support surface. The method includes (a) setting a temperature of the substrate support surface to the same temperature over an entire substrate support surface, (b) etching a first etching target film formed on a substrate disposed on the substrate support substrate, (c) acquiring a first etching rate that is an etching rate of the first etching target film, (d) setting the temperature of the substrate support surface to be concentrically and gradually increased from a central portion to a peripheral edge portion, or to be concentrically and gradually decreased from the central portion to the peripheral edge portion, (e) etching a second etching target film formed on the substrate disposed on the substrate support surface, the second etching target film being the same kind as the first etching target film, (f) acquiring a second etching rate that is an etching rate of the second etching target film, (g) calculating a difference between the first etching rate acquired in (c) and second etching rate acquired in (f), and (h) calculating a deviation amount of the substrate based on the difference calculated in (g).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional plan view illustrating an example of a substrate processing apparatus according to an embodiment of the present disclosure.

FIG. 2 is a diagram illustrating an example of a plasma processing apparatus according to the present embodiment.

FIG. 3 is a diagram illustrating an example of temperature control regions of a main body portion of a substrate support according to the present embodiment.

FIG. 4 is a diagram illustrating an example of a cross section of the main body portion of the substrate support according to the present embodiment.

FIG. 5 is a diagram illustrating an example of temperature conditions for each etching processing according to the present embodiment.

FIG. 6 is a diagram illustrating an example of a contour map and a graph of the etching rates in the X and Y directions according to the present embodiment.

FIG. 7 is a diagram illustrating an example of a contour map and a graph representing the difference between the etching rates in the X and Y directions according to the present embodiment.

FIG. 8 is a diagram illustrating an example of calculating the deviation amount of the center of gravity by a linear approximate formula from the graph representing the difference between the etching rates in the X direction according to the present embodiment.

FIG. 9 is a diagram illustrating an example of calculating the deviation amount of the center of gravity by a linear approximate formula from the graph representing the difference between the etching rates in the Y direction according to the present embodiment.

FIG. 10 is a diagram illustrating an example of the deviation amount of the wafer center with respect to the ESC center according to the present embodiment.

FIG. 11 is a flowchart illustrating an example of a processing of detecting the deviation amount according to the present embodiment.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a method of detecting the deviation amount of a substrate transport position and a substrate processing apparatus disclosed herein will be described in detail with reference to the drawings. The disclosed technology is not limited by the following embodiments.

As described above, when there is a deviation between the center of an ESC and the center of a substrate, radio frequency (RF) characteristics or temperature characteristics become non-uniform, leading to in-plane non-uniformity in the etching rate or the etching shape. It is difficult to quantify such an error in the relative positions between the ESC and the substrate after assembling them into a chamber. Thus, it is anticipated to accurately and simply detect the deviation amount of the relative position between the electrostatic chuck and the substrate.

[Configuration of Substrate Processing Apparatus]

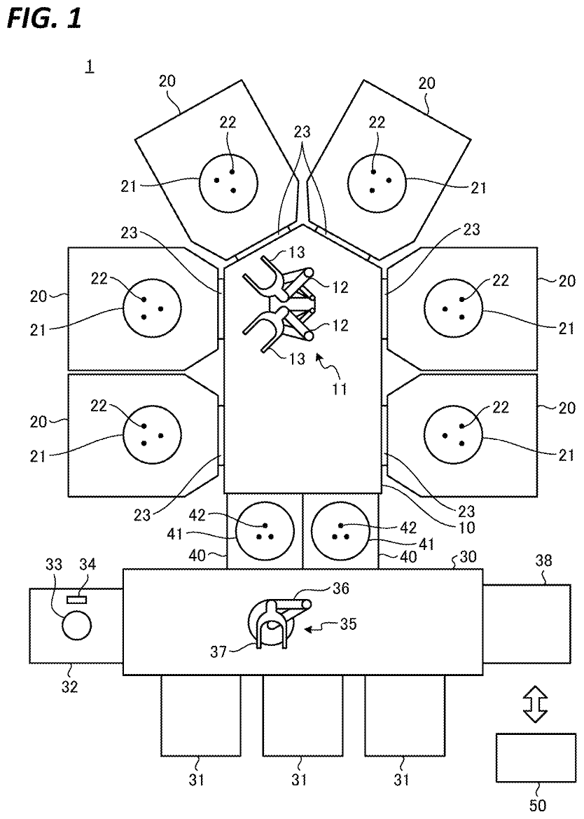

FIG. 1 is a cross-sectional plan view illustrating an example of a substrate processing apparatus according to an embodiment of the present disclosure. The substrate processing apparatus 1 illustrated in FIG. 1 is a substrate processing apparatus capable of performing various types of processings such as a plasma processing on a single substrate (hereinafter also referred to as a wafer).

As illustrated in FIG. 1, the substrate processing apparatus 1 includes a transfer module 10, six process modules 20, a loader module 30, and two load lock modules 40.

The transfer module 10 has a substantially pentagonal shape in plan view. The transfer module 10 has a vacuum chamber in which a transport mechanism 11 is arranged. The transport mechanism 11 includes a guide rail (not illustrated), two arms 12, and a fork 13 arranged at the tip of each arm 12 to support the wafer. Each arm 12 is of a SCARA arm type, and is configured to be pivotable and be freely extendable and retractable. The transport mechanism 11 moves along the guide rail, and transports the wafer to and from the process modules 20 or the load lock modules 40. The transport mechanism 11 is not limited to the configuration illustrated in FIG. 1 as long as it may transport the wafer to and from the process modules 20 or the load lock modules 40. For example, each arm 12 of the transport mechanism 11 may be configured to be pivotable and be freely extendable and retractable, and may also be configured to be freely vertically movable.

The process modules 20 are radially arranged around the transfer module 10 and are connected to the transfer module 10. The process module 20 is an example of a plasma processing apparatus. The process module 20 has a processing chamber and includes a cylindrical substrate support 21 (stage) arranged therein. The substrate support 21 has a plurality of (e.g., three) thin rod-shaped lift pins 22 capable of freely protruding from the upper surface thereof. Each lift pin 22 is arranged on the same circumference in plan view, and is configured to support and lift up the wafer placed on the substrate support 21 by protruding from the upper surface of the substrate support 21 and to place the supported wafer on the substrate support 21 by retracting into the substrate support 21. After the wafer is placed on the substrate support 21, the inside of the process module 20 is depressurized, and a processing gas is introduced into the process module 20. Furthermore, radio-frequency power is applied to the inside of the process module 20 to generate a plasma, and the wafer is plasma-processed by the plasma. The transfer module 10 and the process module 20 are partitioned by a gate valve 23 which is able to be freely opened and closed.

The loader module 30 is arranged to face the transfer module 10. The loader module 30 has a rectangular parallelepiped shape and is an atmospheric transport chamber maintained under an atmospheric pressure environment. Two load lock modules 40 are connected to one longitudinal side of the loader module 30. Three load ports 31 are connected to the other longitudinal side of the loader module 30. A front-opening unified pod (FOUP) (not illustrated), which is a container accommodating a plurality of wafers, is arranged in the load port 31. An aligner 32 is connected to one transverse side of the loader module 30. Further, a transport mechanism 35 is arranged inside the loader module 30. Furthermore, a measurement unit 38 is connected to the other transverse side of the loader module 30.

The aligner 32 performs positioning of the wafer. The aligner 32 includes a rotary stage 33 which is rotated by a drive motor (not illustrated). For example, the rotary stage 33 has a diameter smaller than that of the wafer, and is configured to be rotatable with the wafer placed on the upper surface thereof. An optical sensor 34 is provided near the rotary stage 33 to detect the outer peripheral edge of the wafer. In the aligner 32, the center position of the wafer and the orientation of a notch with respect to the center of the wafer are detected by the optical sensor 34. The wafer is transferred to a fork 37 to be described later so that the center position of the wafer and the orientation of the notch become a predetermined position and a predetermined orientation. Thus, the transport position of the wafer is adjusted such that the center position of the wafer and the orientation of the notch inside the load lock module 40 become the predetermined position and the predetermined orientation.

The transport mechanism 35 includes a guide rail (not illustrated), an arm 36, and the fork 37. The arm 36 is of a SCARA arm type, and is configured to be freely movable along the guide rail and also configured to be pivotable, be extendable and retractable, and be freely vertically movable. The fork 37 is arranged at the tip of the arm 36 to support the wafer. In the loader module 30, the transport mechanism 35 transports the wafer between the FOUP arranged in each load port 31, the aligner 32, the measurement unit 38, and the load lock modules 40. The transport mechanism 35 is not limited to the configuration illustrated in FIG. 1 as long as it may transport the wafer among the FOUP, the aligner 32, the measurement unit 38, and the load lock modules 40.

The measurement unit 38 measures an etching amount with respect to the wafer on which an etching processing has been completed in the process module 20. The measurement unit 38 calculates the etching rate based on the measured etching amount and the time of the etching processing. That is, the measurement unit 38 measures the etching rate. The measurement unit 38 outputs the measured etching rate to a control device 50 to be described later. The measurement unit 38 is not limited to the position adjacent to the loader module 30, and may be arranged inside the loader module 30.

The load lock modules 40 are arranged between the transfer module 10 and the loader module 30. The load lock module 40 has a variable internal pressure chamber, the inside of which is switchable between the vacuum and the atmospheric pressure, and includes a cylindrical stage 41 arranged therein. When loading the wafer from the loader module 30 to the transfer module 10, the inside of the load lock module 40 is maintained at the atmospheric pressure to receive the wafer from the loader module 30. Thereafter, the inside of the load lock module 40 is depressurized to load the wafer into the transfer module 10. Further, when unloading the wafer from the transfer module 10 to the loader module 30, the inside of the load lock module 40 is maintained at the vacuum to receive the wafer from the transfer module 10. Thereafter, the inside of the load lock module 40 is raised to the atmospheric pressure to load the wafer into the loader module 30. The stage 41 has a plurality of (e.g., three) thin rod-shaped lift pins 42 capable of freely protruding from the upper surface thereof. Each lift pin 42 is arranged on the same circumference in plan view, and is configured to support and lift up the wafer by protruding from the upper surface of the stage 41 and to place the supported wafer on the stage 41 by retracting into the stage 41. The load lock module 40 and the transfer module 10 are partitioned by a gate valve (not illustrated) which is able to be freely opened and closed. Further, the load lock module 40 and the loader module 30 are partitioned by a gate valve (not illustrated) which is able to be freely opened and closed.

The substrate processing apparatus 1 includes the control device 50. The control device 50 is, for example, a computer, and includes a central processing unit (CPU), a random access memory (RAM), a read only memory (ROM), an auxiliary storage device, and the like. The CPU operates based on programs stored in the ROM or the auxiliary storage device, and controls an operation of each component of the substrate processing apparatus 1.

[Configuration of Process Module 20]

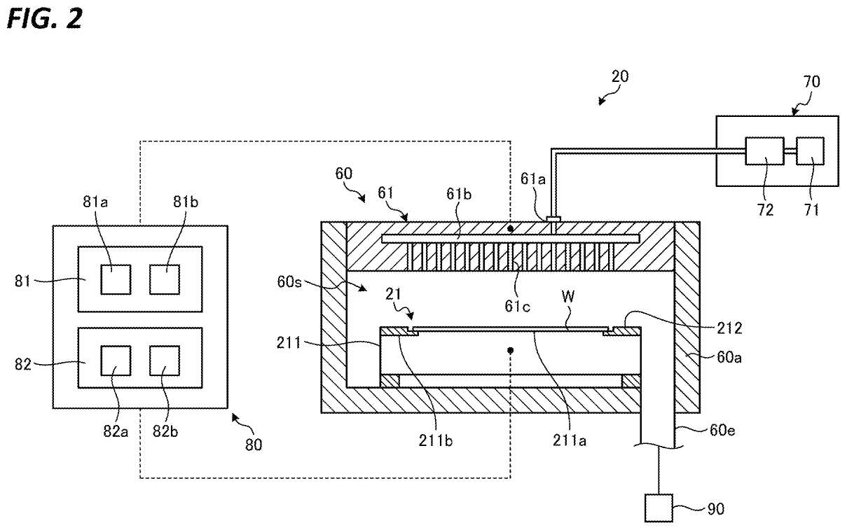

Next, a configuration example of a capacitively-coupled plasma processing apparatus as an example of the process module 20 will be described. In the following description, the process module 20 is also referred to as the capacitively-coupled plasma processing apparatus 20, or simply referred to as the plasma processing apparatus 20. FIG. 2 is a diagram illustrating an example of a plasma processing apparatus according to the present embodiment.

The capacitively-coupled plasma processing apparatus 20 includes a plasma processing chamber 60, a gas supply 70, a power supply 80, and an exhaust system 90. Further, the plasma processing apparatus 20 includes the substrate support 21 and a gas introducer. The gas introducer is configured to introduce at least one processing gas into the plasma processing chamber 60. The gas introducer includes a shower head 61. The substrate support 21 is arranged in the plasma processing chamber 60. The shower head 61 is arranged above the substrate support 21. In one embodiment, the shower head 61 constitutes at least a portion of the ceiling of the plasma processing chamber 60. The plasma processing chamber 60 has a plasma processing space 60s defined by the shower head 61, a sidewall 60a of the plasma processing chamber 60, and the substrate support 21. The sidewall 60a is grounded. The shower head 61 and the substrate support 21 are electrically insulated from a housing of the plasma processing chamber 60.

The substrate support 21 includes a main body portion 211 and a ring assembly 212. The main body portion 211 has a central region (substrate support surface) 211a for supporting a wafer (substrate) W and an annular region (ring support surface) 211b for supporting the ring assembly 212. The annular region 211b of the main body portion 21 surrounds the central region 211a of the main body portion 211 in plan view. The wafer W is placed on the central region 211a of the main body portion 211, and the ring assembly 212 is placed on the annular region 211b of the main body portion 211 so as to surround the wafer W on the central region 211a of the main body portion 211b. In one embodiment, the main body portion 211 includes a base and an electrostatic chuck. The base includes a conductive member. The conductive member of the base functions as a lower electrode. The electrostatic chuck is arranged above the base. The upper surface of the electrostatic chuck has the substrate support surface 211a. The ring assembly 212 includes one or a plurality of annular members. At least one of the one or plurality of annular members is an edge ring. Further, although not illustrated, the substrate support 21 may include a temperature control module configured to control at least one of the electrostatic chuck, the ring assembly 212, and the wafer W to a target temperature. The temperature control module may include a heater, a heat transfer medium, a flow path, or a combination thereof. A heat transfer fluid such as brine or gas flows through the flow path. Further, the substrate support 21 may include a heat transfer gas supply configured to supply a heat transfer gas between the back surface of the wafer W and the substrate support surface 211a.

The shower head 61 is configured to introduce at least one processing gas from the gas supply 70 into the plasma processing space 60s. The shower head 61 has at least one gas supply port 61a, at least one gas diffusion chamber 61b, and a plurality of gas introduction ports 61c. The processing gas supplied to the gas supply port 61a passes through the gas diffusion chamber 61b and is introduced into the plasma processing space 60s from the plurality of gas introduction ports 61c. The shower head 61 includes a conductive member. The conductive member of the shower head 61 functions as an upper electrode. In addition to the shower head 61, the gas introducer may include one or a plurality of side gas injectors (SGI) provided in one or a plurality of openings formed in the sidewall 60a.

The gas supply 70 may include at least one gas source 71 and at least one flow rate controller 72. In one embodiment, the gas supply 70 is configured to supply at least one processing gas from each corresponding gas source 71 to the shower head 61 via each corresponding flow rate controller 72. Each flow rate controller 72 may include, for example, a mass flow controller or a pressure-controlled flow rate controller. Further, the gas supply 70 may include at least one flow rate modulation device that modulates or pulses the flow rate of at least one processing gas.

The power supply 80 includes an RF power supply 81 coupled to the plasma processing chamber 60 via at least one impedance matching circuit. The RF power supply 81 is configured to supply at least one RF signal (RF power) such as a source RF signal and a bias RF signal to the conductive member of the substrate support 21 and/or the conductive member of the shower head 61. Thus, a plasma is formed from at least one processing gas supplied to the plasma processing space 60s. Thus, the RF power supply 81 may function as at least a part of a plasma generator. Further, when a bias RF signal is supplied to the conductive member of the substrate support 21, a bias potential occurs in the wafer W, and ion components in the formed plasma may be drawn to the wafer W.

In one embodiment, the RF power supply 81 includes a first RF generator 81a and a second RF generator 81b. The first RF generator 81a is coupled to the conductive member of the substrate support 21 and/or the conductive member of the shower head 61 via at least one impedance matching circuit, and is configured to generate a source RF signal (source RF power) for plasma generation. In one embodiment, the source RF signal has a frequency in a range of 13 MHz to 150 MHz. In one embodiment, the first RF generator 81a may be configured to generate a plurality of source RF signals with different frequencies. The generated one or plurality of source RF signals are supplied to the conductive member of the substrate support 21 and/or the conductive member of the shower head 61. The second RF generator 81b is coupled to the conductive member of the substrate support 21 via at least one impedance matching circuit, and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 81b may be configured to generate a plurality of bias RF signals with different frequencies. The generated one or plurality of bias RF signals are supplied to the conductive member of the substrate support 21. Further, in various embodiments, at least one of the source RF signal and the bias RF signal may be pulsed.

Further, the power supply 80 may include a DC power supply 82 coupled to the plasma processing chamber 60. The DC power supply 82 includes a first DC generator 82a and a second DC generator 82b. In one embodiment, the first DC generator 82a is connected to the conductive member of the substrate support 21, and is configured to generate a first DC signal. The generated first DC signal is applied to the conductive member of the substrate support 21. In one embodiment, the first DC signal may be applied to another electrode such as an electrode in the electrostatic chuck. In one embodiment, the second DC generator 82b is connected to the conductive member of the shower head 61, and is configured to generate a second DC signal. The generated second DC signal is applied to the conductive member of the shower head 61. In various embodiments, the first and second DC signals may be pulsed. In addition, the first and second DC generators 82a and 82b may be provided in addition to the RF power supply 81, and the first DC generator 82a may be provided in place of the second RF generator 81b.

The exhaust system 90 may be connected to, for example, a gas outlet 60e provided in a bottom portion of the plasma processing chamber 60. The exhaust system 90 may include a pressure regulating valve and a vacuum pump. The pressure in the plasma processing space 60s is regulated by the pressure regulating valve. The vacuum pump may include a turbo molecular pump, a dry pump, or a combination thereof

[Temperature Condition of Etching Processing]

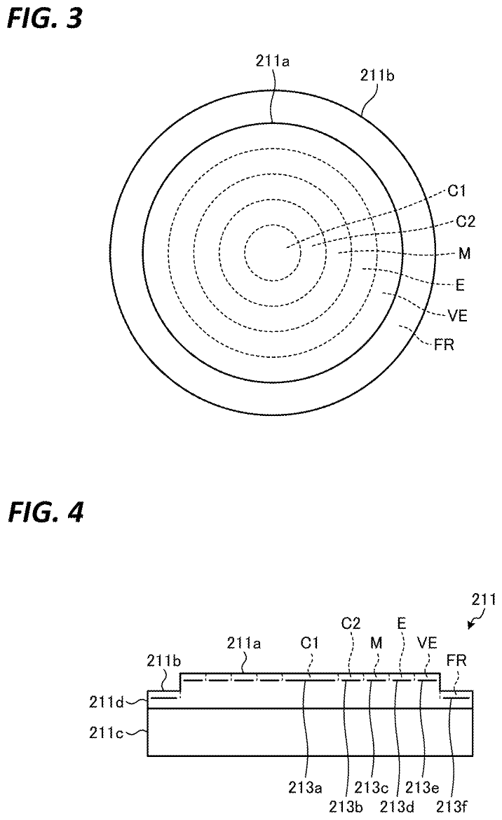

Next, the temperature conditions of an etching processing and the etching rate will be described with reference to FIGS. 3 to 6. First, temperature control regions in the substrate support surface 211a will be described with reference to FIGS. 3 and 4. FIG. 3 is a diagram illustrating an example of temperature control regions of the main body portion of the substrate support according to the present embodiment. As illustrated in FIG. 3, the substrate support surface 211a is divided into five concentric regions in order from a central portion. The five concentric regions of the substrate support surface 211a are designated by C1, C2, M, E, and VE in order from the central portion to a peripheral edge portion. Further, one region of the ring support surface 211b is referred to as a region FR because an edge ring such as a focus ring is arranged thereon. The regions C1, C2, M, E, VE, and FR form concentric temperature control regions.

FIG. 4 is a diagram illustrating an example of a cross section of the main body portion of the substrate support according to the present embodiment. As illustrated in FIG. 4, the main body portion 211 includes a base 211c and an electrostatic chuck 211d. The electrostatic chuck 211d includes heaters 213a to 213f corresponding respectively to the regions C1, C2, M, E, VE, and FR. The heater 213a is a circular heater corresponding to the region C1 at the central portion of the substrate support surface 211a. The heaters 213b to 213e are annular heaters corresponding to the regions C2, M, E, and VE of the substrate support surface 211a. The heater 213f is an annular heater corresponding to the region FR of the ring support surface 211b. The heaters 213a to 213f each enable temperature control individually. That is, the control device 50 is able to control the temperature of the substrate support surface 211a and the ring support surface 211b concentrically. The electrostatic chuck 211d includes an attraction electrode (not illustrated). Further, the regions C2, M, E, VE, and FR may be further divided into a plurality of temperature control regions in the circumferential direction. In this case, the heaters 213b to 213f are also divided so as to correspond to the plurality of divided temperature control regions. Further, the plurality of divided temperature control regions may be controlled to the same temperature in the circumferential direction.

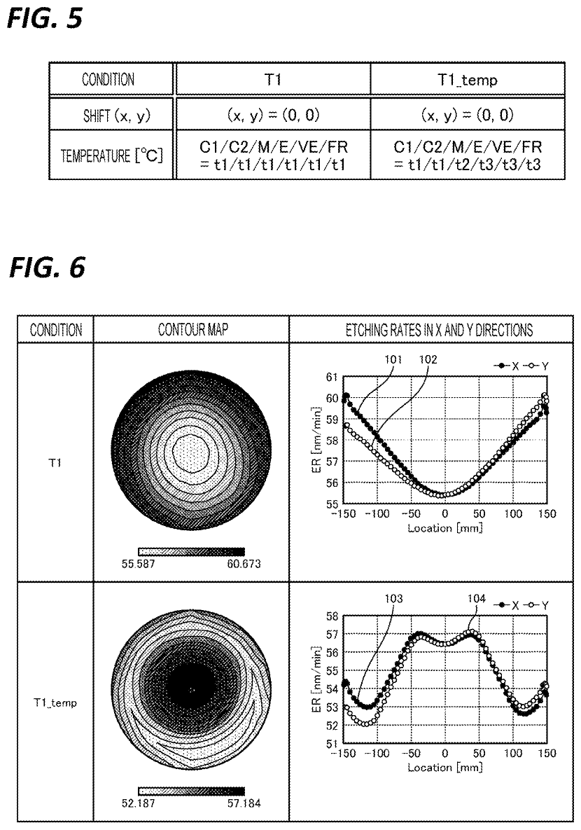

In FIGS. 5 and 6, when etching a silicon nitride film (SiN blanket) formed on the wafer W using a specific recipe that has high temperature sensitivity with respect to the etching rate, the etching rates when the temperature of the wafer W is constant (condition T1) and when the temperature gradient is concentrically formed (condition T1_temp) were acquired.

FIG. 5 is a diagram illustrating an example of temperature conditions for each etching processing according to the present embodiment. As illustrated in FIG. 5, in the condition T1, the shift (x, y) with respect to the transport position of the wafer W in the substrate support surface 211a is set to (0, 0). Further, in the condition T1, the temperature of the regions C1, C2, M, E, VE, and FR in the substrate support surface 211a and the ring support surface 211b is controlled to t1° C.

In the condition T1_temp, the shift (x, y) with respect to the transport position of the wafer W in the substrate support surface 211a is set to (0, 0) as in the condition T1. Further, in the condition T1_temp, for each region, the regions C1 and C2 are controlled to t1° C., the region M is controlled to t2° C., and the regions E and VE are controlled to t3° C. Further, in the condition T1_temp, the region FR in the ring support surface 211b is controlled to t3° C. Here, a relationship between the temperatures t1 to t3 is t1<t2<t3. That is, in the condition T1_temp, the temperature gradient is formed concentrically from t1° C. to t3° C. That is, the concentric temperature gradient in the condition T1_temp is a temperature gradient in which the central portion of the wafer W has a lower temperature than the peripheral edge portion. In other words, the concentric temperature gradient is set such that the temperature of the substrate support surface 211a is concentrically and gradually increased from the central portion to the peripheral edge portion. The concentric temperature gradient may be a temperature gradient in which the central portion of the wafer W has a higher temperature than the peripheral edge portion. That is, the concentric temperature gradient may be set such that the temperature of the substrate support surface 211a is concentrically and gradually decreased from the central portion to the peripheral edge portion. Further, the concentric temperature gradient may be set such that the temperature of the substrate support surface 211a and the ring support surface 211b is concentrically and gradually increased from the central portion to the peripheral edge portion or the ring support surface 211b, or is concentrically and gradually decreased from the central portion to the peripheral edge portion or the ring support surface 211b.

The temperature control of the wafer W may be made by controlling at least the temperature of the substrate support surface 211a, and the temperature control of the ring support surface 211b is not necessarily. The concentric temperature gradient may be formed by at least two temperature regions in the substrate support surface 211a, and is not limited to the five temperature regions of the present embodiment. Further, for example, when no heater is embedded in the substrate support 21, the surface temperature of the wafer W is controlled to the same temperature by equalizing the pressure of a helium gas, which is a heat transfer gas supplied between the substrate support surface 211a and the wafer W, within the substrate support surface 211a (placing surface). Meanwhile, the surface temperature of the wafer W is controlled to form the temperature gradient concentrically by varying the pressure of the helium gas between the central portion and the peripheral edge portion in the substrate support surface 211a. Further, the temperature of each region may be arbitrarily set such that the temperature gradient is formed within a range that may be set by the main body portion 211 of the substrate support 21, for example, a range of 0° C. to 120° C.

FIG. 6 is a diagram illustrating an example of a contour map and a graph of the etching rates in the X and Y directions according to the present embodiment. FIG. 6 illustrates a contour diagram and the etching rates on a straight line in the X and Y directions, which are two different directions, passing through the center of the wafer W, as etching results of the wafer W for the conditions T1 and T1_temp. In the conditions T1 and T1_temp, as an example of the measurement interval of the etching rate, the etching rate was measured at the interval of 5 mm except for the edge portion of the wafer W. In the condition T1, the etching rate is higher at the peripheral edge portion than at the central portion of the wafer W, so that a graph 101 of the etching rate in the X direction and a graph 102 of the etching rate in the Y direction may be obtained. The result of the condition T1 contains a deviation caused by the plasma processing chamber 60.

Meanwhile, in the condition T1_temp, the etching rate is lower at the peripheral edge portion than at the central portion of the wafer W, so that a graph 103 of the etching rate in the X direction and a graph 104 of the etching rate in the Y direction may be obtained. The result of the condition T1_temp contains a deviation caused by the plasma processing chamber 60 and a deviation caused by the temperature of the substrate support surface 211a. The etching rates are not limited to the X and Y directions, and may be those in other directions as long as they include the etching rates in two different directions passing through the center of the wafer W respectively. Further, the etching rates in the two different directions may be the etching rates in two directions perpendicular to each other.

[Calculation of Difference]

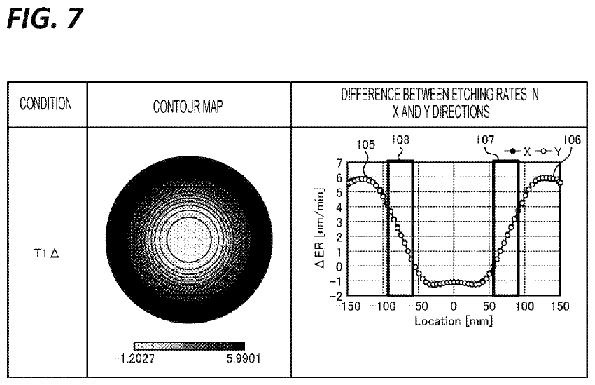

Next, in order to cancel the deviation caused by the plasma processing chamber 60, the difference between the etching rates on a straight line in two different directions, i.e., the X and Y directions, passing through the center of the wafer W are calculated. FIG. 7 is a diagram illustrating an example of a contour map and a graph representing the difference between the etching rates in the X and Y directions according to the present embodiment.

A condition T1Δ illustrated in FIG. 7 represents the difference between the condition T1 and the condition T1_temp. In the condition T1Δ, a graph 105 representing the difference between the graph 101 and the graph 103 of the etching rates in the X direction, and a graph 106 representing the difference between the graph 102 and the graph 104 of the etching rates in the Y direction may be obtained. The contour map of FIG. 7 represents the difference. In the condition T1Δ, the deviation caused by the plasma processing chamber 60 is canceled, and only the deviation caused by the temperature of the substrate support surface 211a is included. That is, since the center of the five concentric circular regions of the substrate support surface 211a corresponds to the center of the substrate support surface 211a, the graphs 105 and 106 of the condition T1Δ represent the deviation amount between the wafer W and the substrate support surface 211a. The required accuracy of the deviation amount may be enhanced by shortening the measurement interval of the etching rate.

Here, note specific corresponding ranges 107 and 108 (e.g., ±60 to 90 mm) in each section from the center (0 mm) of the wafer W to either peripheral edge portion (150 mm, −150 mm). In the ranges 107 and 108, the graphs 105 and 106 are approaching a straight line, so as to correspond to the temperature gradient. Therefore, by obtaining a linear approximate formula for the graphs 105 and 106 in the ranges 107 and 108, the center of gravity of contour lines of the contour map may be obtained, and the position of the wafer W relative to the substrate support surface 211a may be obtained.

[Calculation of Deviation Amount of Center of Gravity]

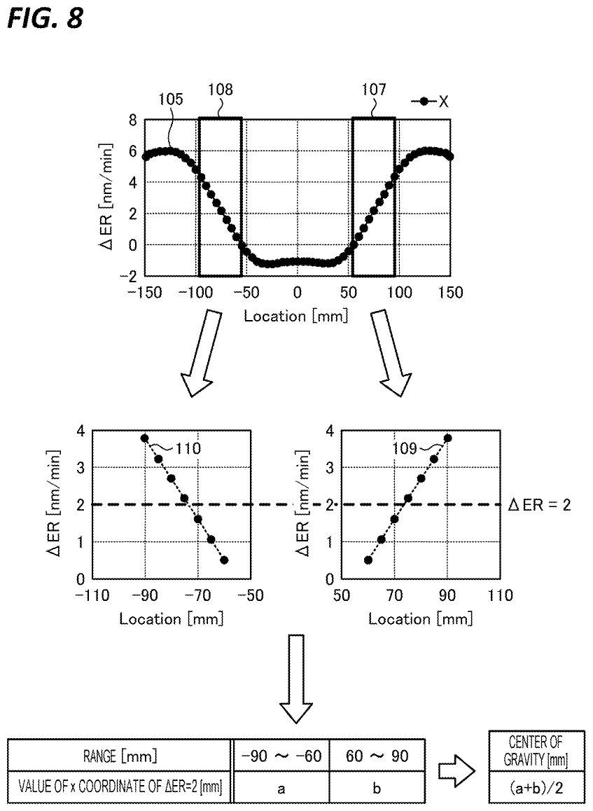

FIG. 8 is a diagram illustrating an example of calculating the deviation amount of the center of gravity by a linear approximate formula from the graph illustrating the difference between the etching rates in the X direction according to the present embodiment. The deviation amount of the center of gravity corresponds to the deviation of the center of gravity of the contour lines of the difference between the etching rates in the contour map illustrated in FIG. 7. As illustrated in FIG. 8, a graph 109 is generated by obtaining a linear approximate formula for the range 107 of the graph 105 in which the distance from the center of the wafer W is on the positive side. Meanwhile, a graph 110 is generated by obtaining a linear approximate formula for the range 108 of the graph 105 in which the distance from the center of the wafer W is on the negative side.

Next, for the graphs 109 and 110, the value of the x coordinate (Location) when the y coordinate is ΔER=2 [nm/min] was b in the range of Location (60 mm to 90 mm) corresponding to the graph 109. Further, the value of the x coordinate (Location) when the y coordinate is ΔER=2 [nm/min] was a in the range of Location (−90 mm to −60 mm) corresponding to the graph 110. The center of gravity may be obtained as (a+b)/2 based on the respective values of the x coordinate when the y coordinate is ΔER=2 [nm/min]. That is, when the center of the wafer W is used as a reference, the center of the substrate support surface 211a deviates by (a+b)/2 in the X direction.

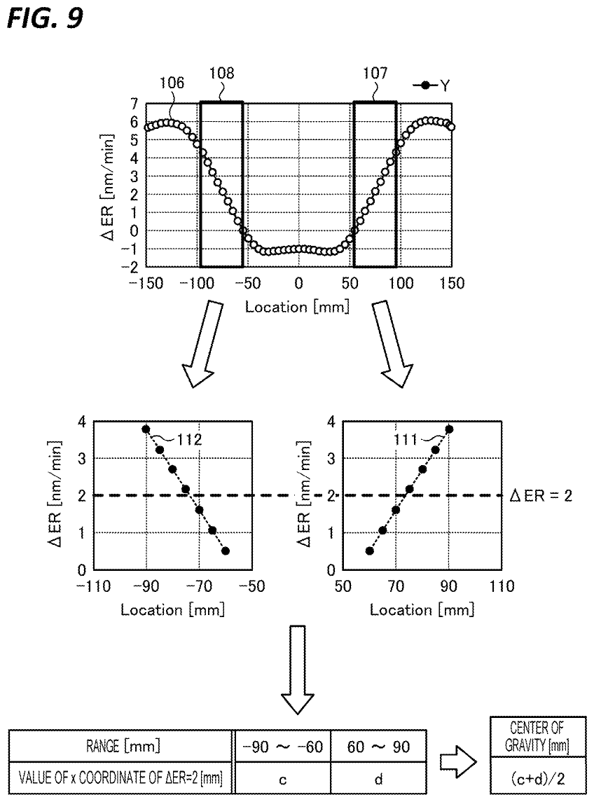

FIG. 9 is a diagram illustrating an example of calculating the deviation amount of the center of gravity by a linear approximate formula from the graph illustrating the difference between the etching rates in the Y direction according to the present embodiment. As illustrated in FIG. 9, a graph 111 is generated by obtaining a linear approximate formula for the range 107 of the graph 106 in which the distance from the center of the wafer W is on the positive side. Meanwhile, a graph 112 is generated by obtaining a linear approximate formula for the range 108 of the graph 106 in which the distance from the center of the wafer W is on the negative side.

Next, for the graphs 111 and 112, the value of the x coordinate (Location) when the y-coordinate is ΔER=2 [nm/min] was d in the range of Location (60 mm to 90 mm) corresponding to the graph 111. Further, the value of the x coordinate (Location) when the y coordinate is ΔER=2 [nm/min] was c in the range of Location (−90 mm to −60 mm) corresponding to the graph 112. The center of gravity may be obtained as (c+d)/2 based on the respective values of the x coordinate when the y coordinate is ΔER=2 [nm/min]. That is, when the center of the wafer W is used as a reference, the center of the substrate support surface 211a deviates by (c+d)/2 in the Y direction. In the graphs 109 to 112, they coordinate for obtaining the value of the x-coordinate is not limited to ΔER=2 [nm/min], and may use any other value such as ΔER=1 [nm/min] or ΔER=3 [nm/min] as long as it is in a linear region.

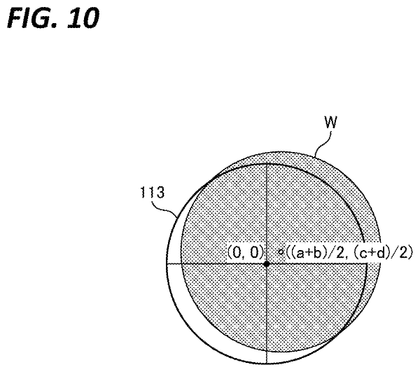

FIG. 10 is a diagram illustrating an example of the deviation amount of the wafer center with respect to the ESC center according to the present embodiment. As illustrated in FIG. 10, when expressing the center of a seal band 113, which is a portion of the substrate support surface 211a in contact with the outermost periphery of the wafer W, as the ESC center (x, y)=(0, 0), the coordinates of the center of the wafer W are obtained based on the center of gravity in each of the X and Y directions, and are expressed as (x, y)=((a+b)/2, (c+d)/2). That is, the deviation amount of the center of the wafer W with respect to the ESC center may be obtained as (x, y)=((a+b)/2, (c+d)/2).

[Method of Detecting Deviation Amount of Substrate Transport Position]

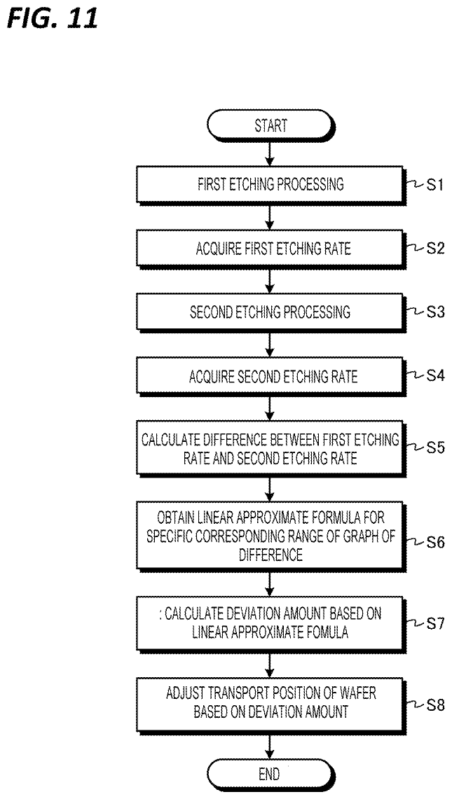

Next, a method of detecting the deviation amount of a substrate transport position in the substrate processing apparatus 1 according to the present embodiment will be described. FIG. 11 is a flowchart illustrating an example of a processing of detecting the deviation amount according to the present embodiment. In the following description, an operation of each component of the substrate processing apparatus 1 is controlled by the control device 50. Further, in the process of detecting the deviation amount illustrated in FIG. 11 will be described as including the adjustment of the substrate transport position based on the detected deviation amount.

The control device 50 performs control to transport the wafer W accommodated in the FOUP of the load port 31 to the process module 20 by way of the loader module 30, the load lock module 40, and the transfer module 10, and to place the wafer W on the substrate support surface 211a of the main body portion 211. For the measurement of the etching rate, the wafer W is formed with, for example, a silicon nitride film as a first etching target film. The film thickness of the silicon nitride film is previously measured in the X and Y directions which are different two directions.

Thereafter, the control device 50 closes an opening to control the exhaust system 90, thereby discharging a gas from the plasma processing space 60s so that the atmosphere in the plasma processing space 60s reaches a predetermined degree of vacuum. Further, the control device 50 controls a temperature control module (not illustrated) such that the temperature of the wafer W is adjusted to the same predetermined temperature. The control device 50 performs control to supply a process gas to the plasma processing space 60s. The process gas may be, for example, a fluorine-containing gas. The control device 50 performs control to execute a first etching processing of etching the wafer W by a plasma of the process gas generated upon supplying a source RF signal and a bias RF signal from the RF power supply 81 (step S1). That is, the control device 50 controls the surface temperature of the wafer W, placed on the substrate support surface 211a (stage) of the substrate support 21, to the same temperature, so that the first etching target film formed over the wafer W is etched under predetermined conditions.

When the first etching processing is completed, the control device 50 performs control to stop the supply of the process gas, the source RF signal and the bias RF signal and to open an opening (not illustrated). The control device 50 performs control to unload the wafer W from the process module 20 and to transport the wafer W to the measurement unit 38 by way of the transfer module 10, the load lock module 40, and the loader module 30.

The control device 50 controls the measurement unit 38 to measure the film thickness of the silicon nitride film, which is the first etching target film, after the first etching processing. The measurement is performed at the same multiple positions as positions of the previous measurement. The control device 50 performs control to acquire a first etching rate for the wafer W from the previously measured film thickness of the silicon nitride film and the film thickness of the silicon nitride film after the first etching processing (step S2). The control device 50 performs control to accommodate the wafer W, for which the first etching rate has been measured, in the FOUP of the load port 31 by way of the loader module 30.

Subsequently, the control device 50 performs control to transport another wafer W accommodated in the FOUP of the load port 31 to the process module 20 by way of the loader module 30, the load lock module 40, and the transfer module 10, and to place the wafer W on the substrate support surface 211a of the main body portion 211. For the measurement of the etching rate, the other wafer W is also formed with a second etching target film (silicon nitride film), which is the same film as in the first etching processing. The film thickness of the silicon nitride film is previously measured at the same multiple positions in the X and Y directions, which are different two directions. Thereafter, the control device 50 closes the opening to control the exhaust system 90, thereby discharging the gas from the plasma processing space 60s so that the atmosphere in the plasma processing space 60s reaches a predetermined degree of vacuum.

Further, the control device 50 controls the temperature control module (not illustrated) such that the temperature of the wafer W is adjusted to a predetermined temperature forming a concentric temperature gradient. That is, the control device 50 controls the temperature of the substrate support surface 211a to be set so as to be concentrically and gradually increased from the central portion to the peripheral edge portion. The control device 50 performs control to supply a process gas to the plasma processing space 60s. The process gas may be, for example, a fluorine-containing gas. The control device 50 performs control to execute a second etching processing of etching the wafer W by a plasma of the process gas generated upon supplying a source RF signal and a bias RF signal from the RF power supply 81 (step S3). That is, the control device 50 controls the surface temperature of the wafer W, placed on the substrate support surface 211a (stage) of the substrate support 21, to form a concentric temperature gradient, so that the second etching target film of the same kind as the first etching target film, formed on the wafer W, is etched under predetermined conditions.

When the second etching processing is completed, the control device 50 controls the measurement unit 38 to measure the film thickness of the silicon nitride film, which is the second etching target film, after the second etching processing as in step S2. The measurement is performed at the same multiple positions as positions of the previous measurement. The control device 50 performs control to acquire a second etching rate for the other wafer W from the previously measured film thickness of the silicon nitride film and the film thickness of the silicon nitride film after the second etching processing (step S4). The control device 50 performs control to accommodate the wafer W, for which the second etching rate has been measured, in the FOUP of the load port 31 by way of the loader module 30. When the silicon nitride film of the wafer W used in the first etching processing has a sufficient thickness, the second etching processing may be performed using that wafer W, and the second etching rate may be calculated from the difference between the amounts of etching. Further, the control device 50 may execute steps S1 and S2 and steps S3 and S4 in a reverse order.

The control device 50 performs control to calculate the difference between the acquired first etching rate and second etching rate for each of the X and Y directions (step S5). That is, the control device 50 performs control to calculate the difference between the first etching rate and the second etching rate on a straight line in the same direction passing through the center of the wafer W for each of the X and Y directions. The control device 50 performs control to obtain a linear approximate formula for a specific corresponding range in each section from the center of the wafer W to either peripheral edge portion, for the graph of the difference in each of the X and Y directions (step S6). The control device 50 performs control to calculate the deviation amount of the wafer W based on the linear approximate formula (step S7). That is, the control device 50 performs control to calculate, for each of the X and Y directions, the value of the x coordinate corresponding to a specific y coordinate in the graph of the linear approximate formula with respect to the positive side and the negative side of the specific corresponding range, and to obtain, as the deviation amount of the center of gravity of the substrate support surface 211a (ESC), a value obtained by dividing the difference between the respective values of the x coordinate by 2. The control device 50 performs control to calculate the coordinates (deviation amount) of the center of the wafer W at the coordinate axes on the basis of the center of the substrate support surface 211a by converting the deviation amount of the center of gravity of the substrate support surface 211a in each of the X and Y directions into the deviation amount of the center of gravity of the wafer W.

The control device 50 performs control to adjust the transport position of the wafer W in the substrate support surface 211a when the transport mechanism 11 transports the wafer W to the process module 20, based on the calculated deviation amount, i.e., the coordinates of the center of the wafer W at the coordinate axes on the basis of the center of the substrate support surface 211a (step S8). In this way, in the substrate processing apparatus 1, it is possible to detect the relative positional deviation amount between an electrostatic chuck (ESC) and a substrate (wafer W) based on the etching rate when the temperature is constant and the etching rate when the temperature gradient is formed. That is, when the detected deviation amount exceeds a predetermined deviation amount, it is possible to determine whether or not to reassemble the ESC. Further, it is possible to cancel a deviation component of the etching rate (RF deviation, edge ring deviation, or the like) other than those caused by the relative positions between the ESC and the wafer W. Furthermore, it is possible to adjust the substrate transport position without opening the plasma processing chamber 60 to the atmosphere during an operation of the substrate processing apparatus 1.

The above embodiment has employed the etching rate of the silicon nitride film formed on the wafer W, but is not limited thereto. The etching rate may be the etching rate of a film having high temperature sensitivity, and for example, may employ the etching rate of a silicon containing film or an organic film. An example of the silicon containing film may include a silicon oxide film in addition to the silicon nitride film described above. Further, an example of the organic film may include a carbon containing film such as a resist.

As described above, according to the present embodiment, the substrate processing apparatus 1 includes the process module 20 in which a stage (main body portion 211) having the substrate support surface 211a is provided inside a chamber (plasma processing chamber 60), the measurement unit 38 configured to measure the etching rate of a substrate (wafer W), and a controller (control device 50) capable of concentrically controlling the temperature of the substrate support surface 211a. (a) The controller is configured to control the substrate processing apparatus 1 so as to set a temperature of the substrate support surface 211a to the same temperature over the entire substrate support surface 211a. (b) The controller is configured to control the substrate processing apparatus 1 so as to etch a first etching target film formed on the substrate. (c) The controller is configured to control the substrate processing apparatus 1 so as to acquire a first etching rate that is an etching rate of the first etching target film. (d) The controller is configured to control the substrate processing apparatus 1 so as to set the temperature of the substrate support surface to be concentrically and gradually increased from a central portion to a peripheral edge portion, or to be concentrically and gradually decreased from the central portion to the peripheral edge portion. (e) The controller is configured to to control the substrate processing apparatus 1 so as to etch a second etching target film formed on the substrate, the second etching target film being the same kind as the first etching target film. (f), the controller is configured to control the substrate processing apparatus 1 so as to acquire a second etching rate that is an etching rate of the second etching target film. (g) The controller is configured to control the substrate processing apparatus 1 so as to calculate a difference between the acquired first etching rate and second etching rate. (h) The controller is configured to control the substrate processing apparatus 1 so as to calculate a deviation amount of the substrate transport position based on the calculated difference. As a result, it is possible to detect the deviation amount of the relative position between an electrostatic chuck (main body portion 211) and the substrate. Further, it is possible to cancel a deviation of the etching rate other than those caused by the relative positions between the electrostatic chuck and the wafer W.

Further, according to the present embodiment, each of the first etching rate and the second etching rate include etching rates in two different directions passing through a center of the substrate. As a result, it is possible to detect the deviation amount of the relative position between the electrostatic chuck and the substrate.

Further, according to the present embodiment, the etching rates in the two different directions are etching rates in two directions perpendicular to each other. As a result, it is possible to detect the deviation amount of relative position between the electrostatic chuck and the substrate.

Further, according to the present embodiment, (g) includes calculating each difference between the first etching rate and the second etching rate on a straight line in the same direction passing through the center of the substrate, and (h) includes obtaining each linear approximate formula for a specific corresponding range in each section from the center of the substrate to either peripheral edge portion when each difference on the straight line is represented by a graph, and calculating the deviation amount based on each linear approximate formula. As a result, it is possible to detect the deviation amount of the relative position between the electrostatic chuck and the substrate.

Further, according to the present embodiment, the substrate support surface has at least two concentric temperature control regions. As a result, it is possible to obtain the difference between the first etching rate and the second etching rate.

Further, according to the present embodiment, the stage has the annular ring support surface 211b on the outer peripheral side of the substrate support surface. (a) includes setting the temperature of the substrate support surface and the temperature of the ring support surface to the same temperature, and (d) includes setting the temperature of the substrate support surface and the ring support surface to be concentrically and gradually increased from the central portion to the peripheral edge portion or the ring support surface 211b, or to be concentrically and gradually decreased from the central portion to the peripheral portion or the ring support surface 211b. As a result, it is possible to detect the deviation amount of the relative position between the electrostatic chuck and the substrate.

Further, according to the present embodiment, the first etching rate and the second etching rate are etching rates of a silicon containing film or an organic film formed on the substrate. As a result, it is possible to detect the deviation amount of the relative position between the electrostatic chuck and the substrate.

Further, according to the present embodiment, the silicon containing film is a silicon nitride film or a silicon oxide film. As a result, it is possible to detect the deviation amount of the relative position between the electrostatic chuck and the substrate.

Further, according to the present embodiment, (i) the controller is configured to control the substrate processing apparatus 1 so as to adjust the substrate transport position based on the calculated deviation amount. As a result, it is possible to adjust the substrate transport position accurately and easily.

Further, according to the present embodiment, the first etching rate and the second etching rate are acquired by being measured in the measurement unit 38. As a result, it is possible to detect the deviation amount of the relative position between the electrostatic chuck and the substrate.

In each embodiment described above, the measurement unit 38 is provided in the substrate processing apparatus 1, but is not limited thereto. For example, a measurement device independent of the substrate processing apparatus 1 may be used to measure and acquire the film thickness before and after an etching processing for the measurement of the etching rate.

Further, in the embodiment described above, the process module 20 that performs a processing such as etching on the wafer W using a capacitively coupled plasma as a plasma source has been described by way of example, but the disclosed technology is not limited thereto. The plasma source is not limited to the capacitively coupled plasma as long as it is a device that performs a processing on the wafer W using a plasma, and may employ any plasma source such as inductively coupled plasma, microwave plasma, or magnetron plasma.

According to the present disclosure, it is possible to detect the deviation amount of the relative position between an electrostatic chuck and a substrate.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A method of detecting a deviation amount of a substrate transport position in a substrate processing apparatus, the substrate processing apparatus including:
a process module in which a stage having a substrate support surface is provided inside a chamber; and
a controller configured to concentrically control a temperature of the substrate support surface,
the method comprising:
(a) setting a temperature of the substrate support surface to a same temperature over an entire substrate support surface;
(b) etching a first etching target film formed on a substrate disposed on the substrate support surface;
(c) acquiring a first etching rate that is an etching rate of the first etching target film;
(d) setting the temperature of the substrate support surface to be concentrically and gradually increased from a central portion to a peripheral edge portion, or to be concentrically and gradually decreased from the central portion to the peripheral edge portion;
(e) etching a second etching target film formed on the substrate disposed on the substrate support surface, the second etching target film being same kind as the first etching target film;
(f) acquiring a second etching rate that is an etching rate of the second etching target film;
(g) calculating a difference between the first etching rate acquired in (c) and second etching rate acquired in (0; and
(h) calculating the deviation amount of the substrate transport position based on the difference calculated in (g).

2. The method according to claim 1, wherein each of the first etching rate and the second etching rate includes etching rates in two different directions passing through a center of the substrate.

3. The method according to claim 2, wherein the etching rates in two different directions are etching rates in two directions perpendicular to each other.

4. The method according to claim 1, wherein, (g) includes calculating each difference between the first etching rate and the second etching rate on a straight line in a same direction passing through the center of the substrate, and
(h) includes obtaining each linear approximate formula for a corresponding range in each section from the center of the substrate to peripheral edge portion of both sides when each difference on the straight line is represented by a graph, and calculating the deviation amount based on each linear approximate formula.

5. The method according to claim 1, wherein the substrate support surface has at least two concentric temperature control regions.

6. The method according to claim 1, wherein the stage has a ring support surface of an annular shape on an outer peripheral side of the substrate support surface,
(a) includes setting the temperature of the substrate support surface and a temperature of the ring support surface to the same temperature, and
(d) includes setting the temperature of the substrate support surface and the temperature of the ring support surface to be concentrically and gradually increased from the central portion to the peripheral edge portion and the ring support surface, or to be concentrically and gradually decreased from the central portion to the peripheral portion and the ring support surface.

7. The method according to claim 1, wherein the first etching rate and the second etching rate are etching rates of a silicon-containing film or an organic film formed on the substrate.

8. The method according to claim 7, wherein the silicon-containing film is a silicon nitride film or a silicon oxide film.

9. The method according to claim 1, further comprising:
(i) adjusting the substrate transport position based on the deviation amount calculated in (h).

10. The method according to claim 1, wherein the substrate processing apparatus further includes a gauge configured to measure an etching rate of the substrate, and
the first etching rate and the second etching rate are measured by the gauge.

11. The method according to claim 1, wherein the first etching target film and the second etching target film are films of same kind that are formed on different substrates.

12. The method according to claim 1, wherein the first etching rate and the second etching rate are measured by a gauge provided inside a loader module.

13. The method according to claim 1, wherein the first etching rate and the second etching rate are measured by a gauge provided adjacent to a loader module.

14. A substrate processing apparatus comprising:
a process module in which a stage having a substrate support surface is provided inside a chamber;
a gauge configured to measure an etching rate of a substrate; and
a controller configured to concentrically control a temperature of the substrate support surface,
wherein the controller is configured to control the substrate processing apparatus to:
(a) set a temperature of the substrate support surface to a same temperature over an entire substrate support surface;
(b) etch a first etching target film formed on a substrate disposed on the substrate support surface;
(c) acquire a first etching rate that is an etching rate of the first etching target film;
(d) set the temperature of the substrate support surface to be concentrically and gradually increased from a central portion to a peripheral edge portion, or to be concentrically and gradually decreased from the central portion to the peripheral edge portion;
(e) etch a second etching target film formed on the substrate disposed on the substrate support surface, the second etching target film being same kind as the first etching target film;
(f) acquire a second etching rate that is an etching rate of the second etching target film;
(g) calculate a difference between the first etching rate acquired in (c) and second etching rate acquired in (0; and
(h) calculate the deviation amount of the substrate transport position based on the difference calculated in (g).

15. The substrate processing apparatus according to claim 14, wherein the gauge is provided inside a loader module.

16. The substrate processing apparatus according to claim 14, wherein the gauge is provided adjacent to a loader module.
